(19) United States
(12) Patent Application Publication
(10) Pub. No.: US 2013/0002262 A1
(43) Pub. Date: Jan. 3, 2013

(54) VEHICLE-MOUNTED SYSTEM AND INSULATION FAILURE DIAGNOSIS UNIT

(75) Inventors: Masakazu TAGO, Aisai-shi (JP); Atsuyuki HIRUMA, Kariya-shi (JP)

(73) Assignee: DENSO CORPORATION, Kariya-city (JP)

(21) Appl. No.: 13/539,803

(22) Filed: Jul. 2, 2012

(30) Foreign Application Priority Data
Jun. 30, 2011 (JP) 2011-145231

(51) Int. Cl. G01R 31/08

(52) U.S. Cl. 324/503

(57) ABSTRACT

A vehicle-mounted system has a high-voltage supply system having a high-voltage battery and a plurality of vehicle-mounted loads electrically connected to the battery. The high-voltage supply system includes a plurality of load portions, each load portion including one or more electric devices which consume or generate electric power. The vehicle-mounted system has a plurality of diagnosis means for detecting an insulation failure. The diagnosis means has an output portion which is connected to the corresponding load portion, and outputs a diagnosis signal. The diagnosis mean has a detector detects a state signal of the system on the basis of the input of the diagnosis signal, and a diagnosis portion which determines whether or not there is an insulation failure.

### CROSS-REFERENCE TO RELATED APPLICATION

This application is based on and claims the benefit of priority from earlier Japanese Patent Application No. 2011-145231 filed Jun. 30, 2011, the description of which is incorporated herein by reference.

### BACKGROUND

1. Technical Field

The present invention relates to an insulation failure diagnosis unit for a vehicle-mounted system having an electric power source and a plurality of electric devices which consume or generate electric power. In particular, the present invention relates to an insulation failure diagnosis unit diagnosis which diagnoses an insulation failure between the system and a vehicle body.

2. Related Art

This kind of insulation failure diagnosis unit is disclosed, for example, in Japanese Patent Application Publication No. 2003-223841. In the insulation failure diagnosis unit, identifying a place where the insulation failure occurs is performed by switching operation states of power inverter circuits connected to the respective loads or switching states of relays which close or open between a high-voltage power source and power inverter circuits.

In the case of using the above-described device, increasing the number of power inverter circuits increases the time required for identifying a place having the insulation failure. When there are a plurality of places having the insulation failures, it may be very difficult to identify the places.

### SUMMARY

The present disclosure provides a vehicle-mounted system and an insulation failure diagnosis unit for diagnosing an insulation failure in the vehicle-mounted system which has a plurality of electric devices, and decreasing the time to diagnose.

An exemplary embodiment provides a vehicle-mounted system, having a first circuit having an electric power source and a plurality of vehicle-mounted loads electrically connected to the electric power source, the first circuit including a plurality of load portions, one of the loads being a traction motor, each load portion being a circuit portion which is a part of the first circuit, each load portion including one or more loads. The vehicle-mounted system a plurality of diagnosis means for detecting an insulation failure between the first circuit and a vehicle body, each diagnosis means connected to a respective load portion.

### BRIEF DESCRIPTION OF THE DRAWINGS

In the accompanying drawings:

FIG. 1 is a schematic view showing configuration of a system in a first embodiment;

FIG. 2 is a flow chart showing a sequence of processes for a diagnosis of an insulation failure in accordance with the first embodiment;

FIG. 3 is a schematic view showing configuration of a system in a second embodiment;

FIG. 4 is a flow chart showing a sequence of processes for a diagnosis of an insulation failure in accordance with the second embodiment;

FIG. 5 is a schematic view showing configuration of a system in a third embodiment;

FIG. 6 is a schematic view showing configuration of a system in a fourth embodiment.

### DETAILED DESCRIPTION OF PREFERRED EMBODIMENTS

### First Embodiment

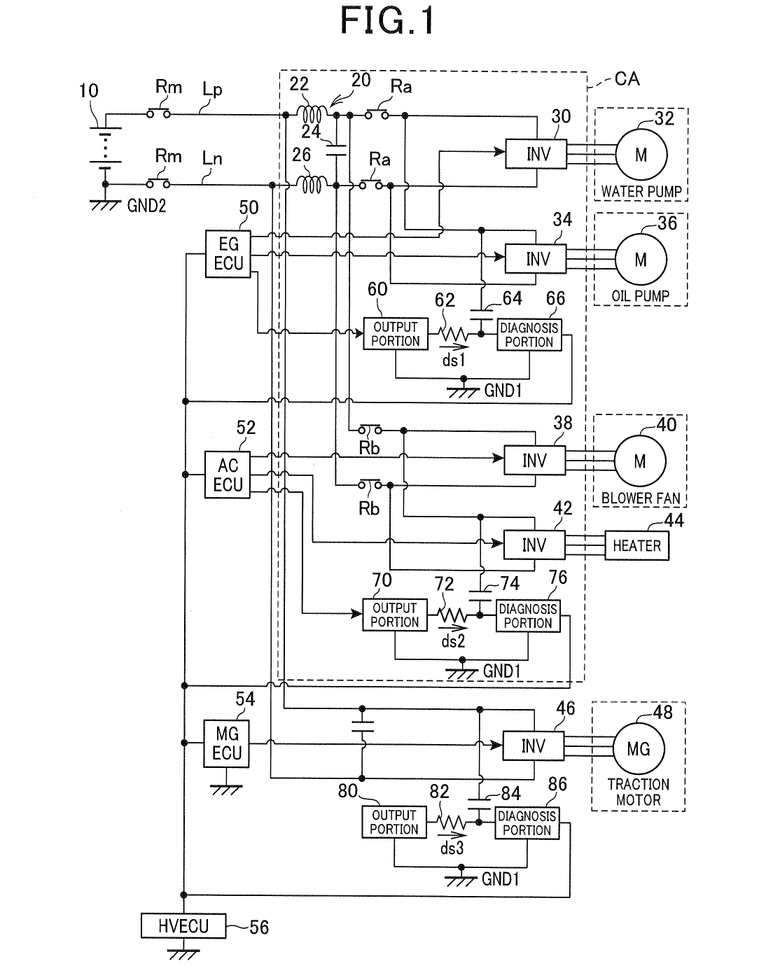

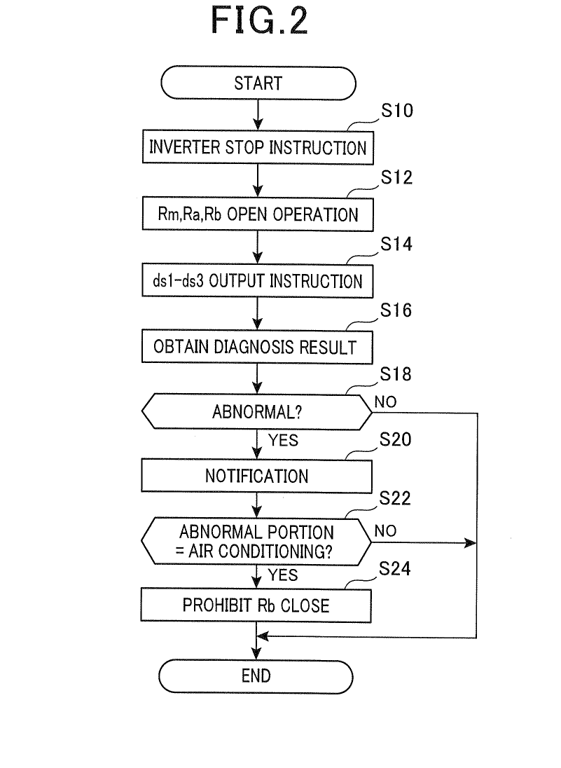

A first embodiment will be described with reference to FIG. 1 and FIG. 2. In the first embodiment, an insulation failure diagnosis unit according to the present invention is applied to a hybrid electric vehicle having a high-voltage supply system.

FIG. 1 shows a configuration of the high-voltage supply system in this embodiment.

The high-voltage supply system (corresponding to a first circuit in claims) has a high-voltage battery 10 as a high-voltage supply, a supply circuit 20, and a plurality of inverters 30, 34, 38, 42, 46 as power inverter circuits. The high-voltage supply system has a plurality of electric loads 32, 36, 40, 44, 48 including a motor generator 48. An insulation failure diagnosis unit that diagnoses whether there is an insulation failure between the vehicle body and the high-voltage supply system is applied to the high-voltage supply system.

The high-voltage battery 10 in FIG. 1 has a secondary battery which is for example about 10 V in terminal voltage. The negative pole of the high-voltage 10 battery is electrically insulated from the vehicle body. Particularly, for example, both terminals of the high-voltage battery 10 are connected to a pair of capacitors, and the connecting point between these capacitors is connected to the vehicle body. Thus, the central value between the positive pole potential and the negative pole potential of the high-voltage battery 10 is set to be equal to the potential of the vehicle body.

The high-voltage battery 10 is connected to a pair of supply lines Lp, Ln, and the pair of supply lines Lp, Ln are opened and closed by a pair of electric relays Rm, Rm. The pair of supply lines Lp, Ln are connected to the supply circuit 20. The supply circuit 20 has a pair of normal mode choke coils 22, 26 and smoothing capacitor 24. The normal mode choke coil 22 is connected to the high-side supply line Lp, and the normal mode choke coil 24 is connected to the low-side supply line Ln. The smoothing capacitor 24 is connected to the pair of supply lines Lp, Ln.

A pair of inverters 30, 34 which supply electric power of the high-voltage to the loads are connected in parallel to the supply circuit 20 through a pair of relays Ra, Ra. The inverter 30 converts the supplied voltage from the high-voltage battery 10 into three-phase alternating voltage, and applies the three-phase alternating voltage to an electric motor 32. The electric motor 32 is mounted in a water pump unit which circulates coolant through a cylinder block of a vehicle-mounted internal combustion. The inverter 34 converts the supplied voltage from the high-voltage battery 10 into three-phase alternating voltage, and applies the three-phase alternating voltage to an electric motor 36. The electric motor 36 is mounted in an oil pump unit which circulates lubricant oil through a powertrain such as a differential gear.

Furthermore, a pair of inverters 38, 42 are connected in parallel to the supply circuit 20 through a pair of relays Rb, Rb. The inverter 38 converts the supplied voltage from the high-voltage battery 10 into three-phase alternating voltage, and applies the three-phase alternating voltage to an electric motor 40. The electric motor 40 is mounted in a blower fan of vehicle-mounted air-conditioning. The inverter 42 converts the supplied voltage from the high-voltage battery 10 into three-phase alternating voltage, and applies the three-phase alternating voltage to an heater 44 mounted in the vehicle-mounted air conditioning. The heater 44 is an electric heater which is driven by a three-phase inverter in this embodiment.

As above described, the supply circuit 20 is shared with a plurality of inverters 30, 34, 38, 42 in this embodiment. This can reduce necessary capacitance. In particular, the capacitance needed when a supply circuit (a smoothing capacitor) is shared with a plurality of inverters is smaller than the capacitance needed for each supply circuit when a plurality of supply circuits are provided for the respective inverters. For reducing necessary capacitance, it is necessary that the inverters 30, 34, 38, 42 are different from each other in switching frequency.

The above described inverters 30, 34, 38, 42 and supply circuit 20 are mounted in a case CA, and the vehicle-mounted electric loads (the electric motor 32, 36, 40 and the heater 44) are disposed outside the case CA. This intends to downsize the case CA and to dispose the case CA at a place where it is less damaged at a time of vehicular crash.

The inverter 46 is connected to the supply lines Lp, Ln. The inverter 46 converts the supplied voltage from the high-voltage battery 10 into three-phase alternating voltage, and applies the three-phase alternating voltage to the motor generator 48 functioning as a traction motor and a generator.

The inverter 30, 34 are controlled by an electric control unit for an engine (EGECU) 50. The inverter 38, 42 are controlled by an electric control unit for an air conditioning (ACECU 52). The inverter 46 is controlled by an electric control unit for a motor generator (MGECU) 54. These ECUs 50, 52, 54 communicate with an upper electric control unit for a hybrid electric vehicle (HVECU) 56 through CAN (controller area network). Alternatively, the electric motor 36 may be controlled by a different ECU from the one for controlling the electric motor 32, because the electric motor 36 tenuously relates to the internal combustion.

These EGECU 50, ACECU 52, MGECU 54 and HVECU 56 configure a low voltage supply system which uses lower voltage than the high-voltage supply system having the high-voltage battery 10. The low voltage supply system is electrically isolated from the high-voltage supply system, and the reference potential of the low voltage supply system is set to be equal to the potential of the vehicle body. Therefore, the low voltage supply system outputs a control signal to the high-voltage supply system through an isolator which allows a system to communicate a signal to another system isolated from each other. The isolator is for example a photo coupler. In particular, when EGECU 50 controls the inverter 30, 34, when ACECU 52 controls the inverter 38, 42, and MGECU 54 controls the inverter 46, the control signals are sent through the isolator.

The following is the explanation of the insulation failure diagnosis unit in this embodiment.

Here, in this embodiment, the electrical loads are divided into a plurality of load groups. The one of the load groups, a first load group, includes the electric motor 32, 36 as vehicle-mounted auxiliary machinery of a powertrain. The other one, a second load group, includes the electric motor 40 and the heater 44 as vehicle-mounted auxiliary machinery of a vehicle-mounted air conditioning. The other one, a third load group, includes the motor generator 48.

In this embodiment, the insulation failure diagnosis unit has a plurality of insulation failure diagnosis devices connected to the high-voltage supply system. Each insulation failure diagnosis device as hardware for diagnosing the insulation failure corresponds to a respective load group, and connecting points each of which the respective insulation failure diagnosis device connects to are different from each other. More particularly, in this embodiment, each insulation failure diagnosis device is connected to a respective point closer to the corresponding load group than the points at which the non-corresponding insulation failure diagnosis devices are connected. Here, “close” means not spatially but electrically or in term of circuit, more specifically.

Each of the insulation failure diagnosis devices has an output portion which outputs a diagnosis signal for diagnosing the insulation failure to the high-voltage supply system, a series-connected element as a detector, and, a diagnosis portion which diagnoses whether there is the insulation failure. A capacitor and a resistor are connected in series in the series-connected element.

In particular, the one of the insulation failure diagnosis devices, a first insulation failure diagnosis device corresponding to the first load group, has the output portion 60, the series-connected element in which a capacitor 64 and a resistor 62 are connected in series, and, the diagnosis portion 66. The insulation failure diagnosis device is connected between a ground GND1 (vehicle body potential) and the high-side line of the inverter 34. The insulation failure diagnosis device is connected closer to the inverter 34 than the relay Ra is. In particular, the output portion 60 is connected to the high-side line through the capacitor 64 and the resistor 62. The diagnosis portion 66 is connected to the connecting point between the resistor 62 and the capacitor 64. In the drawings, the label “GND2” means a reference potential different from “GND1”.

The output portion 60 outputs an alternating voltage signal as a diagnosis signal ds1 and the high-voltage supply system in response to an instruction signal output from EGECU 50. In this embodiment, the output portion 60 has a diagnosis signal generating circuit such as an oscillator. The diagnosis portion 66 receives the diagnosis signal ds1 as a potential at the connecting point between the resistor 62 and the capacitor 64.

In a case where there is an insulation failure between the vehicle body and a first load portion (for example, the electric motors 32, 36), a resistance between the vehicle body and the first load portion appears due to the insulation failure. The resistance due to the insulation failure is described as “imaginary insulation failure resistance” below. The first load portion is a portion of the high-voltage supply system closer to the first load group than the relays Ra, Ra are. That is to say, the pair of relays Ra, Ra are disposed between the first load portion and the other portions of the high-voltage supply system, the first load portion being separated or sectioned from the other portions by relays. The first load portion is connected to the first insulation failure diagnosis device. The voltage of the diagnosis signal ds1 is divided by the imaginary insulation failure resistance and the resistor 62. Therefore, the diagnosis portion 66 can diagnose the insulation failure on the basis of the peak value of the diagnosis signal ds1 and determines the insulation failure is occurring in the target load group when the peak value is smaller than the peak value when there is no insulation failure. The diagnosis portion 66 has, for example, a comparator and a divider for generating a reference voltage compared with the diagnosis signal by the comparator. Configurations disclosed in Japanese Patent Application Publication No. 08-70503 can be used as the detailed configurations of the output portion 60 and the diagnosis portion 66.

Similarly, another of the insulation failure diagnosis devices, a second insulation failure diagnosis device corresponding to the second load group, has the output portion 70, the series-connected element in which a capacitor 74 and a resistor 72 are connected in series, and, the diagnosis portion 76. The insulation failure diagnosis device is connected between a ground GND1 and the high-side line of the inverter 42. The insulation failure diagnosis device is connected closer to the inverter 42 than the relays Rb, Rb are. In particular, the output portion 70 is connected to the high-side line through the capacitor 74 and the resistor 72. The diagnosis portion 76 is connected to the connecting point between the resistor 72 and the capacitor 74. The output portion 70 outputs an alternating voltage signal as a diagnosis signal ds2 and the high-voltage supply system in response to an instruction signal output from ACECU 52. The diagnosis portion 76 receives the diagnosis signal ds2 as potential at the connecting point between the resistor 72 and the capacitor 74. The diagnosis portion 76 diagnoses an insulation failure between the vehicle body and a second load portion on the basis of the received diagnosis signal ds2. The second load portion is a portion of the high-voltage supply system closer to the second load group than the relays Rb, Rb are, including the second load group. That is to say, the pair of relays Rb, Rb are disposed between the second load portion and the other portions of the high-voltage supply system. The second load portion is connected to the second insulation failure diagnosis device.

Another of the insulation failure diagnosis devices, a third insulation failure diagnosis device corresponding to the third load group, has the output portion 80, the series-connected element in which a capacitor 84 and a resistor 82 are connected in series, and, the diagnosis portion 86. The insulation failure diagnosis device is connected between a ground GND1 and the high-side line of the inverter 46. The insulation failure diagnosis device is connected closer to the inverter 46 than the relays Rm, Rm are. In particular, the output portion 80 is connected to the high-side line through the capacitor 84 and the resistor 82. The diagnosis portion 86 is connected to the connecting point between the resistor 82 and the capacitor 84. The output portion 80 outputs an alternating voltage signal as a diagnosis signal ds3 and the high-voltage supply system in response to an instruction signal output from MGECU 54. The diagnosis portion 86 receives the diagnosis signal ds3 as a potential at the connecting point between the resistor 82 and the capacitor 84. The diagnosis portion 86 diagnoses an insulation failure between the vehicle body and a third load portion on the basis of the received diagnosis signal ds3. The third load portion is a portion of the high-voltage supply system closer to the third load group than the relays Rm, Rm are. That is to say, the plural sets of relays Ra, Rb, Rm are disposed between the third load portion and the other portions of the high-voltage supply system. The third load portion is connected to the third insulation failure diagnosis device.

FIG. 2 is a flow chart showing a sequence of processes for a diagnosis of an insulation failure in accordance with this embodiment. Performing the diagnosis is repeated under the control by HVECU 56, for example, at predetermined intervals.

In the sequence of processes, at first, HVECU 56 outputs stop instructions for stopping the operations of the inverters 30, 34, 38, 42, 46 in the step S10. In response to the instructions, EGECU 50, ACECU 52 and MGECU 54 stop the operations of the inverters. In the following step S12, all of the relays Rm, Ra, Rb are opened. This process is for allowing each insulation failure diagnosis device to diagnose the insulation failure in the respective corresponding load portion. For example, opening the relays Ra, Ra interrupts the electrical connection between the target load group for the diagnosis (the electric motor 32, 36) and the non-target load groups (the electric motor 40, heater 44, motor generator 48), which limits the propagation range of the diagnosis signal ds1 to the target load portion.

Next, in step S14, HVECU 56 sends output instructions for outputting the diagnosis signals ds1, ds2, ds3. In response to the instructions, EGECU 50, ACECU 52 and MGECU 54 control the respective output portions 60, 70, 80 to output the respective diagnosis signals ds1, ds2, ds3. The diagnosis portions 66, 76, 86 output respective diagnosis results on the basis of the diagnosis signals ds1, ds2, ds3 with communications through Controller Area Network (CAN).

HVECU 56 receives the diagnosis results from the diagnosis portions 66, 76, 86 in step S16, and determines whether there is at least one load group diagnosed with an abnormal condition where the load group has the insulation failure in step S18. If there is the load group having the insulation failure, HVECU 56 provides a notification of the failure in step S20. The notification may be provided by using a display on a vehicle, by alarming and so on.

In a following step S22, HVECU 56 determines whether or not the second load portion has the insulation failure. If the second load portion has the insulation failure, HVECU 56 prohibits the relays Rb, Rb from being closed in step S24.

The sequence of the processes is completed when the process of the step S24 has finished, or when the results of the determination in the step S18 or S22 are “NO”.

This embodiment described above in detail brings about following effects.

(1) The vehicle-mounted electric loads are sectioned to a plurality of load groups, and the insulation failure diagnosis means (output portion 60, resistor 62, capacitor 64 and diagnosis portion 66; output portion 70, resistor 72, capacitor 74 and diagnosis portion 76; output portion 80, resistor 82, capacitor 84 and diagnosis portion 86) are provided to the respective load groups. These configurations make determining which load group has the insulation failure easy.

(2) The relays Ra, Rb are provided for isolating the load portions from each other. By using these relays, the place having the insulation failure can be narrowed.

(3) If the load group of the vehicle-mounted air conditioning has the insulation failure, the relays Rb, Rb are controlled not to be closed. This interrupts the connection between the high-voltage supply and means which affects the driving function of the vehicle very little, and allows power supply to other loads to be maintained. Thus, problems due to the insulation failure are prevented without affecting the drive of the vehicle.

### Second Embodiment

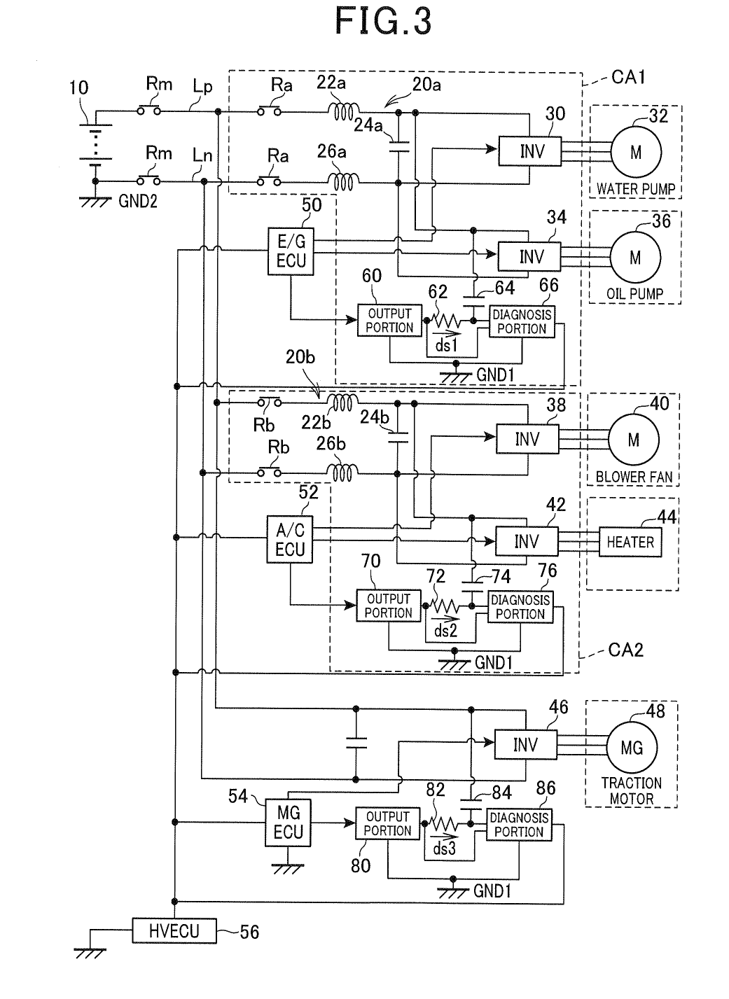

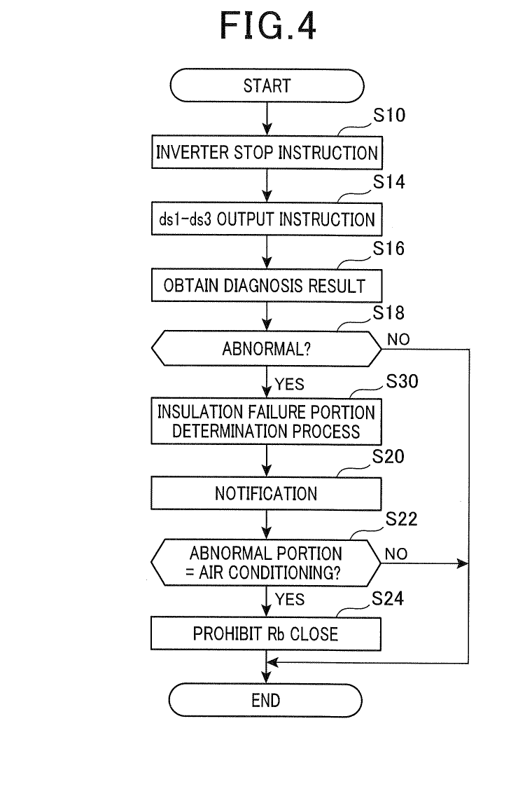

A second embodiment will be described with reference to FIG. 3 and FIG. 4, focusing on differences from the first embodiment.

FIG. 3 shows a system configuration in this embodiment. Parts in FIG. 3 corresponding to parts in FIG. 1 are provided with the same labels, for convenience.

As shown in FIG. 3, the high-voltage supply system has a plurality of supply circuits 20a, 20b in this embodiment. Each of the supply circuits 20a, 20b is connected to a respective inverter, and supplies electric power to a respective load group. The supply circuits 20a, 20b are connected in parallel to the supply lines Lp, Ln, and each of the supply circuits 20a, 20b has a smoothing capacitor and a pair of normal mode choke coils as high-impedance elements. The normal mode choke coils 22a, 26a, 22b, 26b have functions as filter circuits which damp switching noise of the inverters, in a similar way to the first embodiment. Furthermore, in this embodiment, the normal mode choke coils have functions for sectioning or separating the respective load portions and make differences between the diagnosis signal when the insulation failure occurs in the respective load portions and the diagnosis signal when the insulation failure occurs out of the respective load portions, as described below. The supply circuit 20a and the inverters 30, 34 connected to the first load group are disposed in a case CA1, and the supply circuit 20b and the inverters 38, 42 connected to the second load group are disposed in another case CA2.

In this embodiment, the diagnosis portions 66, 76, 86 of the insulation failure diagnosis devices get original signals ds1, ds2, ds3 in addition to the diagnosis signals ds1, ds2, ds3 which have been applied to the high-voltage supply system, which contain information of insulation failures, and are obtained at the connecting points between the resistors 62, 72, 82 and the capacitors 64, 76, 82. The original diagnosis signals are outputted from the output portions to the diagnosis portions 66, 76, 86 without being supplied to the high-voltage supply system and before passing through the resistors 62, 72, 82.

FIG. 4 is a flow chart showing a sequence of processes for a diagnosis of an insulation failure in accordance with this embodiment. Performing the diagnosis is repeated under the control by HVECU 56, for example, at predetermined intervals. Processes in FIG. 4 corresponding to processes in FIG. 2 are provided with the same labels, for convenience.

As shown FIG. 4, after the inverters are stopped (step S10), HVECU 56 sends output instructions for outputting the diagnosis signals ds1, ds2, ds3 without controlling the relays Rm, Ra, Rb to be opened (step S14). Then, HVECU 56 gets the detection results from the diagnosis portions 66, 76, 86 (step S16).

Here, the diagnosis portion 66 outputs information on phase difference as the detection result in addition to the information on peak value. The information on peak value is that whether the peak value of the diagnosis signal received as the potential at the connecting point between the resistor 62 and the capacitors 64 is equal to or lower than the predetermined value. The information on phase difference is related to the phase difference between the original diagnosis signal ds1 and the diagnosis signal ds1 received at the connecting point between the resistor 62 and the capacitors 64.

In a similar way, the diagnosis portion 76 outputs information on phase difference as the detection result in addition to the information on peak value. The information on peak value is that whether the peak value of the diagnosis signal received as the potential at the connecting point between the resistor 72 and the capacitors 74 is equal to or lower than the predetermined value. The information on phase difference is related to the phase difference between the original diagnosis signal ds2 and the diagnosis signal ds2 received at the connecting point between the resistor 72 and the capacitors 74.

The diagnosis portion 86 outputs information on phase difference as the detection result in addition to the information on peak value. The information on peak value is that whether the peak value of the diagnosis signal received as the potential at the connecting point between the resistor 82 and the capacitors 84 is equal to or lower than the predetermined value. The information on phase difference is related to the phase difference between the original diagnosis signal ds3 and the diagnosis signal ds3 received at the connecting point between the resistor 82 and the capacitors 84.

Next, HVECU 56 determines whether the peak value of the diagnosis signal is equal to or lower than the predetermined value in at least one detection result, based on the received detection results (step S18). If the peak value of the diagnosis signal is equal to or lowers than the predetermined value in at least one detection result, HVECU 56 determines the high-voltage system is in an abnormal condition (step S18; YES). In this case, HVECU 56 specifies an abnormal place where the insulation failure occurs, based on the information on phase difference (step S30).

Specifying the abnormal space can be performed, for example as follows. If an insulation failure of the line between the electric motor 32 and the inverter 32, for example, occurs, the potential at the connecting point between the resistor 62 and the capacitor 64 is lower than the one in normal condition, because the diagnosis signal is divided by the resistor 62 and the imaginary insulation failure resistance. In this case, however, the phase difference between the original diagnosis signal ds1 and the diagnosis signal ds1 received at the connecting point between the resistor 62 and the capacitor 64 is not large.

On the other hand, if an insulation failure of the line between the electric motor 40 and the inverter 38, for example, occurs, the diagnosis signal ds1 received at the connecting point between the resistor 62 and the capacitor 64 is divided by the imaginary insulation failure resistance, the resistor 62 and the normal mode choke coils 22a, 22b. In particular, the potential at the connecting point between the resistor 62 and the capacitor 64 becomes the potential between the resistor 62 and the normal mode choke coil 22a in a series-connected element in which the imaginary insulation failure resistance, the resistor 62 and the normal mode choke coils 22a, 22b are connected in series. The phase difference of the diagnosis signal ds1 occurs because the normal mode choke coils 22a, 22b have properties of shifting the phase of the diagnosis signal ds1.

As this, a difference in impedance between a loop path formed when the insulation failure occurs in the corresponding load portion and another loop path formed when the insulation failure occurs out of the corresponding load portion is made. Therefore, if the peak value of the diagnosis signal ds1 received by the diagnosis portion 66 is smaller but the phase difference of the diagnosis signal ds1 doesn't occur, it can be determined that the insulation failure occurs in the first load group. In this case, the peak values of the diagnosis signals ds2, ds3 received by the diagnosis portions 76, 86 are smaller and the phase differences of the diagnosis signals ds2, ds3 occur.

That is to say, in a case that the peak value of the diagnosis signal received by only one diagnosis portion for an load group e is smaller but the phase difference of the diagnosis signal doesn't occur; the peak values of the diagnosis signals received by the other diagnosis portions for the other load groups are smaller and the phase differences of the diagnosis signals ds2, ds3 occur, it can be determined that the insulation failure occurs in the only one load group.

Following the above-described step S30, furthermore, detecting the location of the abnormality by operating the relays Rm, Ra, Rb in the same way as the first embodiment may be performed. This makes it possible to detect the location of the abnormality in such a complicated case that the insulation failures occur in two or more place.

### Third Embodiment

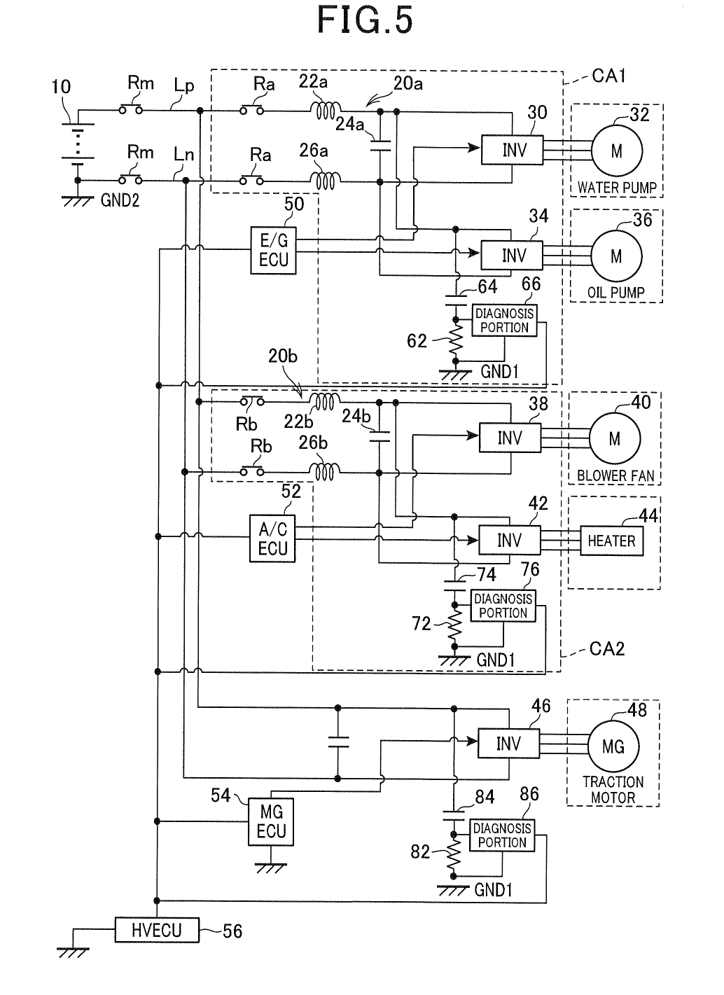

A third embodiment will be described with reference to FIG. 5, focusing on differences from the second embodiment.

FIG. 5 shows a system configuration in this embodiment. Parts in FIG. 5 corresponding to parts in FIG. 3 are provided with the same labels, for convenience.

As shown in FIG. 5, the output portions 60, 70, 80 shown in FIG. 3 are deleted in this embodiment. In particular, the capacitor 64 and the resistor 62 are connected between the inverter 34 and ground GND1, the capacitor 74 and the resistor 72 are connected between the inverter 42 and ground GND1, and the capacitor 84 and the resistor 82 are connected between the inverter 46 and ground GND1.

In place of the output portions 60, 70, 80 shown in FIG. 3, the inverters 30, 34, 38, 42, 46 are used as output portions which output alternating current signals, the diagnosis signals, in this embodiment. For example, general three phase inverters each of which has a positive pole input terminal, a negative pole input terminal, three output terminals connected to the corresponding load, three high side switching elements which switch between the positive pole input terminal and the output terminals, and, three low side switching elements which switch between the negative pole input terminal and the output terminals are used as the inverters 30, 34, 38, 42, 46. In this example using a three phase inverter, each high side switching element and each low side switching element of each phase are turned ON alternately (complementary-drive). If there is no insulation failure, the potential between the capacitor 64 and the resistor 62 hardly changes during the complementary-drive. On the other hand, if an insulation failure occurs, the potential between the capacitor 64 and the resistor 62 changes in synchronization the complementary-drive because an alternating current flows through a loop path formed by the imaginary insulation failure resistance, the resistor 62 and the capacitor 64. In this embodiment, additional hardware as the output portion need not be provided.

The complementary-drive of only one-phase may be performed, because this can generate an alternating current. It is desirable that the complementary-drives of all phase (all output terminals) of the respective inverters 30, 34, 38, 42, 46 are performed. This enables an insulation failure occurring between any output terminal and a load to be detected without being affected by windings of the loads and so on.

Incidentally, in the same way as the first embodiment, the high-voltage supply system is grounded through a series-connected element in which a capacitor and a resistor are connected in series.

### Fourth Embodiment

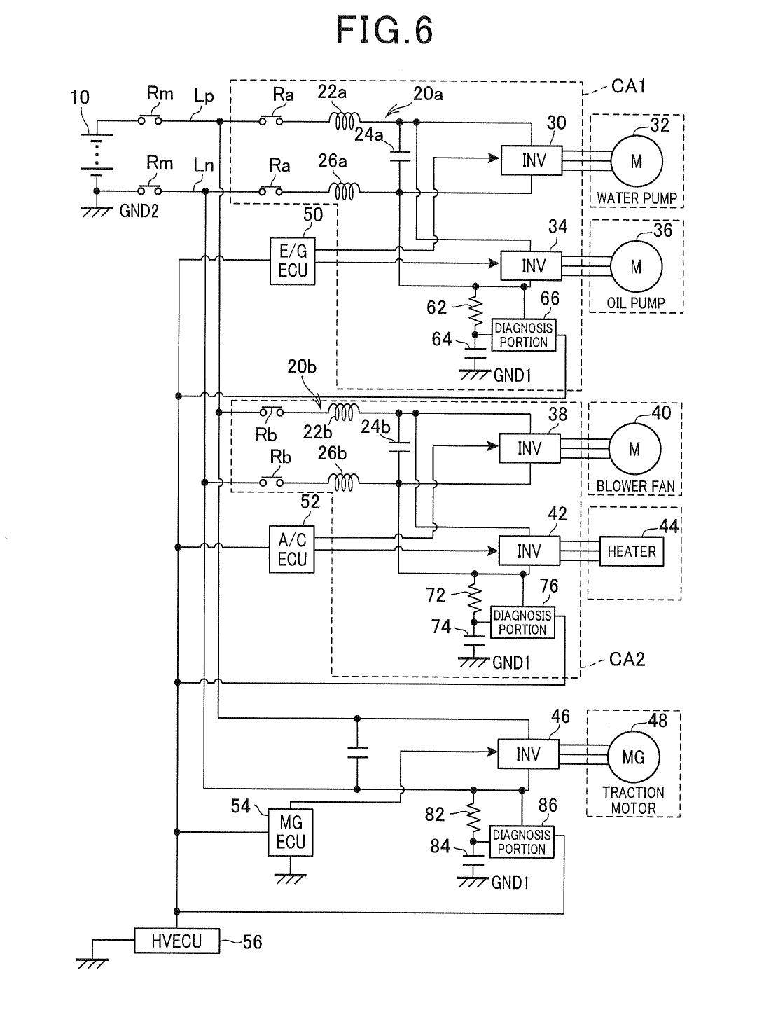

A fourth embodiment will be described with reference to FIG. 6, focusing on differences from the third embodiment.

FIG. 6 shows a system configuration in this embodiment. Parts in FIG. 6 corresponding to parts in FIG. 5 are provided with the same labels, for convenience.

In this embodiment, the diagnosis portion 66, 76, 86 operate in high-side. In particular, the resistor 62 is connected to the high-side input terminal of the inverter 34, the capacitor 64 is grounded and potential at the connecting point between the resistor 62 and the capacitor 64 is input to the diagnosis portion 66. The resistor 72 is connected to the high-side input terminal of the inverter 42, the capacitor 74 is grounded and potential at the connecting point between the resistor 72 and the capacitor 74 is input to the diagnosis portion 76. The resistor 82 is connected to the high-side input terminal of the inverter 46, the capacitor 84 is grounded and potential at the connecting point between the resistor 82 and the capacitor 84 is input to the diagnosis portion 86. The diagnosis portion 66, 76, 86 output the diagnosis result signals, for example through photo couplers.

### <Other Modifications>

Other embodiments and configurations are also within the scope of the present invention as follows.

### [About High-Impedance Element]

The high-impedance element is not limited to the normal mode choke coil. For example, a common mode choke coil may be used. In this case, applying same diagnosis signals having the same phase and the same voltage to a pair of lines, the high-side line and the low-side line, can prohibits the diagnosis signals from being output to the downstream side of the common mode choke coil (the downstream side is closer to the high-voltage battery than the upstream side). Therefore, the diagnosis range can be limited to the upstream side of the common mode choke coil (the upstream side is closer to the load than the downstream side).

The high-impedance element is not limited to the element having an inductor. For example, a resistor as a linear element may be used. It can make a distinguishable difference in peak value of the diagnosis signal between the insulation failure in the upstream side of the resistor and the insulation failure in the downstream side of the resistor.

### [About Diagnosis Conditions]

During the diagnosis process, the inverters need not to be stopped. If the inverter is operated during the diagnosis process, the corresponding diagnosis portion may be provided with a filter circuit which damps signals having a switching frequency of the inverter.

### [About the Diagnosis Portion]

The diagnosis method is not limited to the above-described method. For example, the diagnosis portion may determine which load portion has an insulation failure on the basis of the diagnosis signals ds1, ds2 and the diagnosis signals ds1, ds2 output by the output portion 60, 70 in the second embodiment. For example, when there is an insulation failure between the electric motor 36 and the vehicle body, there is a difference in peak value between the diagnosis signal ds1 received by the diagnosis portion 66 and the diagnosis signal ds2 received by the diagnosis portion 76. It is because the diagnosis signal ds2 received by the diagnosis portion 76 is divided by the resistor 72, the normal mode choke coils 22b, 22a and the imaginary insulation failure resistance. In other words, the diagnosis portion can determine which place, in the corresponding load portion or external portion, has the insulation failure on the basis of a quantity of either phase or peak value without using both of phase and peak value. In this case, it may be determined by comparing the diagnosis signals received by a plurality of diagnosis portions or by comparing the diagnosis signal received by a diagnosis portion with a step-by-step threshold values.

### [About Electric Loads]

Electric loads which the present invention can be applied to are not limited to the above-described loads. For example, an actuator of a motor-operated air-conditioning compressor for vehicle-mounted air-condition units may be used. A cooling fan for a radiator in which coolant of a vehicle-mounted internal combustion engine circulates may be used too. Furthermore, an electric motor included in a pump unit for circulating coolant which cools switching elements of the inverter 46 connected to the motor generator 48 may be used. Actuators (electric motors) included in assist means, for example power steering system which supports to steer vehicles may be used.

### [About Load Group]

The load groups are not limited to the above-described groups. For example, a load group may include temperature controlling means (air-conditioning devices) for controlling a temperature of a cabin and temperature controlling means (e.g. a water pump, the cooling fan of the radiator) for controlling a temperature of a vehicle-mounted powertrain. In this case, if the power supply to the load group is interrupted, power for driving the vehicle is reduced, but the vehicle can drive. Therefore, a limp home process may be performed with the connection between the load group and the high-voltage battery 10.

### [About an Interrupter]

It is not need to provide with an interrupter for each electric group. For example, the relays Ra, Ra may be deleted in the second embodiment.

### [About Electrical State Quantity (State Signal)]

In the present invention, state signals used for detecting the insulation failure are not limited to potential (peak value or phase of voltage) at the connecting point between the resistor and the capacitor. For example, voltage drop quantity or current value between both ends of each resistor 62, 72, 82 may be used.

### [About Diagnosis Means]

In the third and fourth embodiment, a diagnosis portion may be used in common with all of the load groups, in place of the diagnosis portions 66, 76, 86 corresponding to the respective load groups. In similar way, a resistor and a capacitor may be used in common with all of the load groups, in place of the resistor 62 and the capacitor 64, the resistor 72 and the capacitor 74, and, the resistor 82 and the capacitor 84 corresponding to the respective load groups. In this case, it depends on the load group having the insulation failure whether a loop path having the imaginary insulation failure resistance, the resistor and the capacitor includes the normal mode choke coils. Therefore, considering it is desirable.

In third and fourth embodiment, the output portion 80 shown in FIG. 1 may be used only for the load group including the motor generator 48 in place of the inverter 46 as an output portion, because the inverter 46 connected to machinery treating high-power such as a traction motor.

The insulation failure diagnosis unit of the present invention is not limited to the above-described one. For example, the one disclosed in Japanese Patent Application Publication No. 08-70503 may be used.

### [Others]

The high-voltage power source is not limited to the high-voltage battery 10, for example a fuel cell battery may be used.

The present invention may be applied not only to hybrid electric vehicles but also fuel-cell powered vehicles or electric-powered vehicles which have means accumulating only electric energy as energy accumulating means for vehicle-mounted traction motor.

Though the invention has been described with respect to a specific preferred embodiment, many variations and modifications will become apparent to those skilled in the art upon reading the present application. It is therefore the intention that the claims be interpreted as broadly as possible in view of the prior art to include all such variations and modifications.

What is claimed is:

1. A vehicle-mounted system, comprising:
a first circuit having an electric power source and a plurality of vehicle-mounted loads electrically connected to the electric power source, the first circuit including a plurality of load portions, one of the loads being a traction motor, each load portion being a circuit portion which is a part of the first circuit, each load portion including one or more loads;
a plurality of diagnosis means for detecting an insulation failure between the first circuit and a vehicle body, each diagnosis means connected to a respective load portion.

2. The system according to claim 1, wherein
each of the diagnosis means comprises an output circuit which is connected to the corresponding load portion, and outputs a diagnosis signal; and
at least one of the diagnosis means comprises
a detector that detects a state signal of the system on the basis of the input of the diagnosis signal, and
a diagnosis circuit which determines whether or not there is the insulation failure between the system and a vehicle body on the basis of the state signals.

3. The system according to claim 1, wherein
the diagnosis means is configured to determine which load portion in the first circuit has the insulation failure.

4. The system according to claim 2, wherein
the output circuit outputs an alternating current signal as the diagnosis signal; and
the detector is connected between the load portion and the vehicle body.

5. The system according to claim 4, wherein
the first circuit comprises a high impedance element, the high impedance element being disposed between the electric power source and the load portion, the high impedance element having higher impedance than impedance of a line between the electric power source and the high impedance element.

6. The system according to claim 4, wherein
the first circuit further comprises a plurality of supply circuits in the respective load portions, each of the supply circuits supplying electric power of the electric power source to the loads in the respective load portion;
the supply circuit has a high impedance element, the high impedance element having higher impedance than impedance of a line between the electric power source and the supply circuit; and
the detector is connected to a point which is closer to the corresponding loads than the high impedance element is.

7. The system according to claim 2, wherein
the first circuit system further comprises a power inverter circuit having a positive pole input terminal, a negative pole input terminal, an output terminal which is connected to the load, a first switching element which switches between the positive pole input terminal and the output terminal, and, a second switching element which switches between the negative pole input terminal and the output terminal; and
the output portion is configured to control the first and second switching elements of the power inverter circuit to be in an on state alternately so that the power inverter circuit outputs the diagnosis signal.

8. The system according to claim 1, wherein
the first circuit further comprises an interrupter which interrupts the electrically connection between the electric power source and one of the load portions selectively.

9. The system according to claim 8, wherein
the diagnosis means is configured to determine which load portion in the first circuit has the insulation failure; and
the first circuit further comprises a controller which controls the interrupter to interrupt the connection between the electric power source and the load portion having the insulation failure on the basis of the diagnosis result by the diagnosis means.

10. The system according to claim 9, wherein
the system has a first load portion including one or more loads as temperature control devices for a temperature of the vehicle and other load portions including other loads; and
the interrupter interrupts the electrical connection between the electric power source and the first load portion, the other load portions being connected to the electric power source on the basis of the control by the controller.

11. The system according to claim 10, wherein
the temperature control devices for a temperature of the vehicle are temperature control devices for a cabin temperature.

12. The system according to claim 6, wherein
the diagnosis circuit is configured to determine which load portion has the insulation failure on the basis of the state signals.

13. The system according to claim 2, further comprising an interrupter which interrupts the electrically connection between the electric power source and the load portions to be diagnosed selectively, wherein
the detectors are configured to detect the respective state signals with the connection between the electric power source and the corresponding load portions interrupted; and
the diagnosis circuit is configured to determine which load portion has the insulation failure on the basis of the state signals.

14. The system according to claim 6, further comprising an interrupter which interrupts the electrically connection between the electric power source and the load portions to be diagnosed selectively, wherein
the detectors are configured to perform a first and a second detection, the first detection being to detect the corresponding state signal with the corresponding load portion connected to the electric power source, the second detection being to detect the corresponding state signal with the connections of the electric power source and the corresponding load portion interrupted, the second detection being performed on the basis of the result of the first detection; and
the diagnosis circuit is configured to determine which load portion has the insulation failure on the basis of the state signals detected by the first and second detection.

15. The system according to claim 2, wherein
the diagnosis circuit is configured to determine the insulation failure on the basis of two or more state signals from each load portion, the state signals being different in type from each other.

16. An insulation failure diagnosis unit which is applied to a vehicle-mounted system, the system having an electric power source and a plurality of vehicle-mounted loads which are electrically connected to the electric power source, one of the loads being a traction motor, comprising:
a plurality of output circuits each of which is connected to a respective load portion and outputs a diagnosis signal, the respective load portion being a circuit portion which is a part of the system and including one or more of the loads;
a detector which is connected to the respective load portion, and detects a state signal of the system on the basis of the input of the diagnosis signal; and
a diagnosis circuit which determines whether or not there is an insulation failure between the system and a vehicle body on the basis of the state signals.
